(19) United States
(12) Patent Application Publication
(10) Pub. No.: US 2011/0297982 A1
(43) Pub. Date: Dec. 8, 2011

(54) Optoelectronic Semiconductor Chip

(76) Inventors: Norbert Linder, Shanghai (CN); Ralph Wirth, Mintraching-Auhof (DE); Christopher Wiesmann, Furstenfeldbruck (DE); Ross Stanley, Epalinges (CH); Romuald Houdre, St. Sulpice( VD) (CH)

(21) Appl. No.: 13/061,514

(22) PCT Filed: Jul. 23, 2009
(86) PCT No.: PCT/DE2009/001038

§ 371 Date: May 23, 2011

(30) Foreign Application Priority Data
Aug. 29, 2008 (DE) 10 2008 045 028.6

(51) Int. Cl. H01L 33/60

(52) U.S. Cl. 257/98; 257/E33.072

(57) ABSTRACT

A semiconductor chip is specified, comprising an active layer provided for emitting an electromagnetic radiation, and a two-dimensional arrangement of structural units, which is disposed downstream of the active layer in a main emission direction of the semiconductor chip. The structural units are arranged in an arbitrary statistical distribution. Such an arrangement of structural units makes it possible to realize a semiconductor chip having a directional emission characteristic.

This patent application claims the priority of German Patent Application 10 2008 045 028.6, the disclosure content of which is hereby incorporated by reference.

The present application relates to a semiconductor chip which emits electromagnetic radiation, comprising an active layer provided for emitting the electromagnetic radiation. The chip has a two-dimensional arrangement of structural units, which is disposed downstream of the active layer in a main emission direction of the semiconductor chip.

Radiation-emitting semiconductor chips are known in which a two-dimensional photonic crystal is disposed downstream of the active layer in a main emission direction. A two-dimensional photonic crystal in the literal sense has a two-dimensional arrangement—which is periodic in two dimensions—of regions having different refractive indices. Photonic crystals influence the propagation of electromagnetic radiation by diffraction and interference.

Analogously to crystals having an electronic band structure, photonic crystals have a photonic band structure. The photonic band structure can have, in particular, ranges of forbidden energy in which electromagnetic waves cannot propagate within the crystal. These are referred to as photonic band gaps.

One example of a radiation-emitting semiconductor chip comprising a two-dimensional photonic crystal is described in U.S. Pat. No. 5,955,749. Said document specifies that increased coupling out of radiation from the semiconductor chip can be realized by means of such a photonic crystal.

One object is to specify a semiconductor chip of the type mentioned in the introduction in which an emission characteristic that is advantageous for specific applications is set. The semiconductor chip is intended to have, in particular, a directional emission characteristic in which the electromagnetic radiation is emitted for the most part within a relatively narrow emission cone. The so-called Lambertian emission characteristic of a Lambertian surface emitter, which has an approximately direction-independent radiation density, could be designated as a reference with respect to a directional emission characteristic. In addition, emission in which the electromagnetic radiation is for the most part emitted into shallow angles may also be desirable (sub-Lambertian emission).

A semiconductor chip which emits electromagnetic radiation is specified, having an active layer provided for emitting the electromagnetic radiation. The semiconductor chip comprises a two-dimensional arrangement of structural units, which is disposed downstream of the active layer in a main emission direction of the semiconductor chip. The structural units are arranged in an arbitrary statistical distribution.

In one embodiment, the arbitrary statistical distribution of the structural units meets the boundary condition that the distribution of the distances from nearest neighboring structural units has a standard deviation of at least +/−10% and at most +/−25% from an average value.

The structural units are volumes which laterally adjoin regions having a different refractive index. In other words, there is a refractive index jump between the structural units and the laterally adjoining regions.

The expression “laterally” above is taken to mean a direction parallel to a main extension plane of the active layer or of the semiconductor chip. Vertically corresponds to a direction perpendicular to a main extension plane of the active layer or of the semiconductor chip.

The structural units can be, in particular, cutouts in a material layer or elevations extending away from a material layer. The material layer can be a semiconductor layer, in particular. The structural units can comprise solid material and laterally adjoin a region filled with a gas, in particular air. Conversely, the structural units can also be regions which are filled with a gas, in particular air, and which laterally adjoin a region comprising a solid material. However, it is also possible for either the structural units or the laterally adjoining region to comprise a solid material, wherein the refractive index of the structural units can be less than and also greater than that of the laterally adjoining regions.

A two-dimensional arrangement is an arrangement along an area. The area can be planar. However, it can also be a curved area, in principle.

The structural units are arranged in an arbitrary statistical distribution, that is to say that they are not arranged in accordance with a deterministic mathematical algorithm. The arrangement of the structural units does not follow any regularity; it is not a periodic arrangement nor, in particular, an aperiodic arrangement which is created according to a predetermined regularity. Quasi-crystalline arrangements do not come under an arbitrary, statistical distribution either.

The arrangement of the structural units is, moreover, not an arrangement which is based on a periodic arrangement and in which the position of the structural units deviates arbitrarily but slightly from the regular structure, with deviations of, for example, 10% or 20% of a lattice constant of the periodic arrangement. An arrangement which is based on a periodic arrangement and in which the structural units are arranged with arbitrary slight deviations from the sites of the periodic arrangement is nevertheless a substantially periodic arrangement. In the case of a precise arrangement, a regular diffraction pattern is obtained upon electromagnetic radiation being radiated through in the far field. In the case of slight arbitrary deviations from the regular arrangement, the diffraction pattern is merely blurred, but it remains the same diffraction pattern.

The arbitrary statistical distribution of the structural units is not subject to a deterministic mathematical algorithm, but in accordance with one embodiment meets the boundary condition that the distribution of the distances of the nearest neighbors has a standard deviation of at least +/−10% and at most +/−25% from an average value. In the case of the arrangement of the structural units, in particular a pair distribution function describing the lateral distances between the neighboring structural units can have a maximum at one specific distance or a plurality of specific distances.

The expression standard deviation implies that some distances can also deviate at less than 10% or by more than 25% from the average value. The expression standard deviation is an expression that is well defined and well known to the person skilled in the art from statistics.

It has been found that an arbitrary statistical distribution of structural units, particularly under the boundary conditions mentioned above, can be suitable for acting in a similar manner to a photonic crystal. In particular, a directional emission characteristic can be realized. Compared with a periodic crystal, a more homogeneous emission characteristic can be realized by means of the completely irregular, statistically distributed arrangement. A scattering of the electromagnetic radiation at the structural units produces a ring without a discernible substructure, in particular, in the far field.

A directional emission characteristic can be realized by means of the arrangement of the structural units. In the case of the directional emission characteristic, a greater proportion of an electromagnetic radiation is emitted into a specific emission cone, for example plus/minus 30°, than without the arrangement of the structural units.

The structural units are suitable for influencing the propagation of the electromagnetic radiation. For this purpose, in accordance with one expedient embodiment, the structural units in each case have a first lateral extent, a second lateral extent measured perpendicularly to the first lateral extent, and/or a vertical extent, which is greater than or equal to 0.2 times a wavelength of the emission maximum of the electromagnetic radiation and less than or equal to five times a wavelength of the emission maximum of the electromagnetic radiation.

The first lateral extent is measured along any desired first lateral direction. Instead of “extent” the expression “extension” or “spatial extension” can also be used, in principle. It is a one-dimensional size of the structural unit over which the structural unit extends along the first lateral direction. The second lateral extent is the one-dimensional extent of the structural unit measured perpendicularly to the first extent, that is to say to the first lateral direction.

The first lateral direction for measuring the first lateral extent is preferably identical for all the structural units, that is to say the first lateral extents are oriented parallel to one another. Alternatively, it is possible, for example, for the maximum lateral extent in each case to be chosen as the first lateral extent for each structural unit.

A radiation-emitting semiconductor chip emits not just radiation having a single wavelength, but rather an emission spectrum having a maximum.

In one embodiment, the first lateral extent, the second lateral extent and the vertical extent of the structural units are each greater than 0.2 times a wavelength of the emission maximum of the electromagnetic radiation. Additionally or alternatively, in accordance with a further embodiment, the first lateral extent, the second lateral extent and the vertical extent of the structural units are each less than five times a wavelength of the emission maximum of the electromagnetic radiation.

An additional embodiment provides for the first lateral extent, the second lateral extent and/or the vertical extent of the structural units to deviate by less than or at most 10% from the corresponding value of the respective other structural units.

In one configuration of the semiconductor chip, the area of a projection of the structural units onto a main extension plane of the active layer deviates in each case at most slightly from the corresponding area of the other structural units. The deviation of the area can be less than or at most 20%, preferably less than or at most 15%, particularly preferably less than or at most 10%. It goes without saying that it is also possible for the area of the structural units substantially not to deviate from one another.

In accordance with a further-reaching embodiment, the first lateral extent, the second lateral extent and/or the vertical extent is in each case of substantially identical magnitude for the majority of the structural units or for all the structural units. In accordance with a further configuration, the majority of the structural units or all the structural units are substantially of identical size and shaped identically.

In one expedient embodiment of the semiconductor chip, the structural units are formed in a layer comprising semiconductor material. The layer preferably terminates a semiconductor layer sequence of the semiconductor chip in the main emission direction. It can consist of a single material layer or comprise a plurality of layers having different material compositions. In a further embodiment of the semiconductor chip, the structural units are formed in a plurality of layers. The structural units can extend over a plurality of layers of a semiconductor layer sequence of the semiconductor chip and in particular also over all the semiconductor layers of the semiconductor chip.

In one configuration, the active layer of the chip is part of an epitaxial semiconductor layer sequence. The semiconductor layer sequence is provided with a reflector layer on a side lying opposite the main emission side of the semiconductor chip. Such a reflector layer in combination with the structural units can have an additional positive influence on the realization of a directional emission characteristic of the semiconductor chip.

In a further embodiment, the semiconductor chip is free of an epitaxial substrate. The semiconductor chip has epitaxial semiconductor layers that are grown on an epitaxial substrate during production. The epitaxial substrate is at least partly removed afterward, however, such that the resulting semiconductor chip is free of an epitaxial substrate.

In connection with the reflector layer, one additional configuration provides for a carrier element to be contained in the semiconductor chip. The reflector layer is arranged between the carrier element and the semiconductor layer sequence.

Further advantages, embodiments and developments of the semiconductor chip will become apparent from the exemplary embodiments explained below in conjunction with the figures, in which:

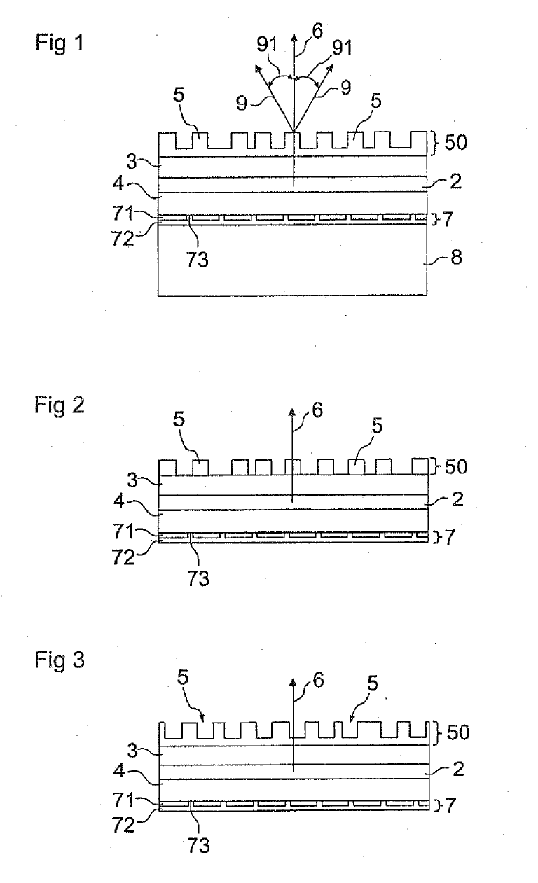

FIG. 1 shows a schematic lateral sectional view of the semiconductor chip in accordance with a first exemplary embodiment,

FIG. 2 shows a schematic lateral sectional view of the semiconductor chip in accordance with a second exemplary embodiment,

FIG. 3 shows a schematic lateral sectional view of the semiconductor chip in accordance with a third exemplary embodiment,

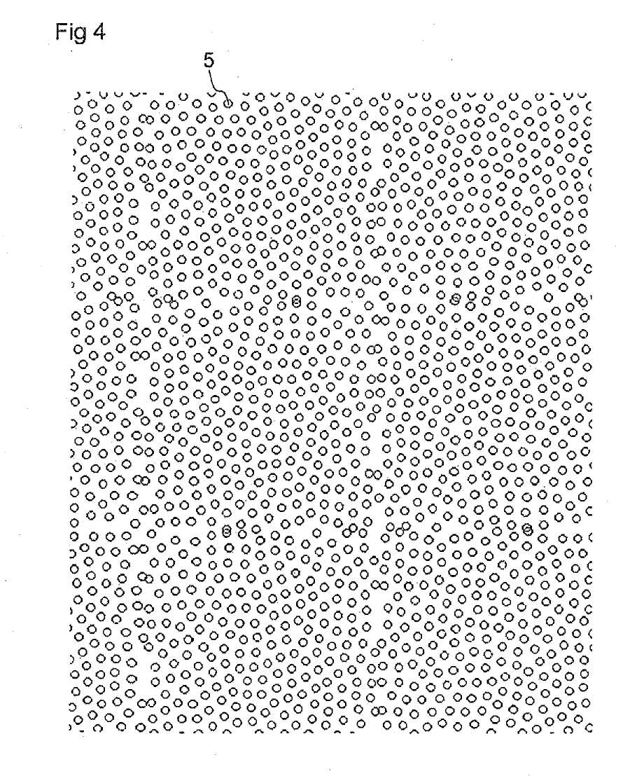

FIG. 4 shows a schematic plan view of an arrangement of structural elements which is suitable for the semiconductor chip,

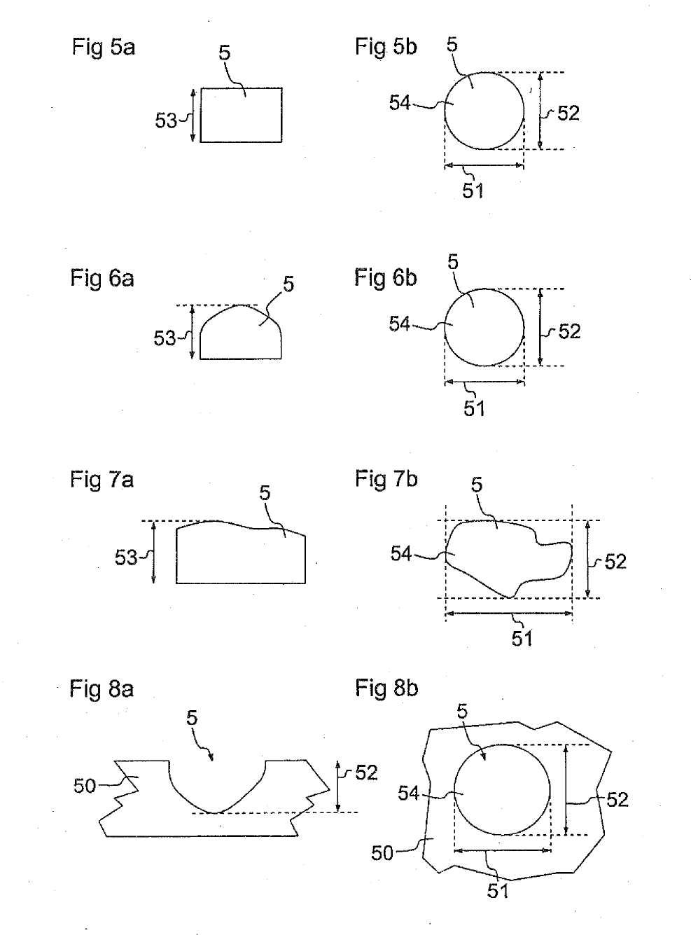

FIGS. 5a, 6a, 7a and 8a show schematic lateral sectional views of structural elements in accordance with different exemplary embodiments, and

FIGS. 5b, 6b, 7b and 8b show schematic plan views of the structural units illustrated in FIGS. 5a, 6a, 7a and 8a in accordance with the different exemplary embodiments.

A lateral view is taken to mean an illustration at a viewing angle which runs in a lateral direction with respect to the semiconductor chip or with respect to the cross section of the semiconductor chip. A plan view is taken to mean an illustration at a viewing angle which runs vertically with respect to the semiconductor chip.

In the exemplary embodiments and figures, identical or identically acting constituent parts are in each case provided with the same reference symbols. The constituent parts illustrated and also the size relationships of the constituent parts among one another should not be regarded as true to scale. Rather, some details of the figures are illustrated with an exaggerated size in order to afford a better understanding.

The semiconductor chip illustrated in FIG. 1 has epitaxial semiconductor layers 2, 3, 4. Each of these semiconductor layers can have, in principle, a plurality of epitaxial sublayers, which are not illustrated.

The semiconductor chip has structural units 5 in the form of elevations or projections. The structural units can likewise comprise or consist of epitaxial semiconductor material. They are formed in a layer 50. It is also possible for the layer 50 not to comprise epitaxial semiconductor material, but rather to comprise or be formed from an inorganic material such as glass, for example.

The layer 50 is disposed downstream of epitaxial semiconductor layers 2, 3, 4 in the main emission direction 6. If the layer 50 comprises a semiconductor material, it terminates the semiconductor layer sequence of the semiconductor chip in the main emission direction 6, for example. It is possible for additional material to be disposed downstream of the layer 50 and the structural units 5 in the main emission direction 6, said additional material not being illustrated in the figures for reasons of clarity.

The semiconductor layer sequence comprises, for example, an active layer 2, a first cladding layer 3 and a second cladding layer 4. The first cladding layer 3 and the second cladding layer 4 are in each case doped with at least one dopant and have a mutually different conduction type. By way of example, the first cladding layer 3 is doped in n-conducting fashion and the second cladding layer 4 is doped in p-conducting fashion. The opposite case can also be implemented, however.

The semiconductor chip can, for example, be based on a nitride, phosphide or arsenide compound semiconductor.

In the present connection, “based on nitride compound semiconductor material” means that the semiconductor layers of the chip or at least one part thereof, particularly preferably at least the active zone, comprises or consists of a nitride compound semiconductor material, preferably AlₙGaₘInₗ₋ₙ₋ₘN, where 0≦n≦1, 0≦m≦1 and n+m≦1. In this case, this material need not necessarily have a mathematically exact composition according to the above formula, but rather, it can comprise for example one or more dopants and additional constituents. For the sake of simplicity, however, the above formula only includes the essential constituents of the crystal lattice (Al, Ga, In, N), even if these can be replaced and/or supplemented in part by small amounts of further substances.

In this connection “based on phosphide compound semiconductor material” means that the semiconductor layer sequence or at least one part thereof, particularly preferably at least the active zone, preferably comprises AlₙGaₘInₗ₋ₙ₋ₘP or AsₙGaₘInₗ₋ₙ₋ₘP, where 0≦n≦1, 0≦m≦1 and n+m≦1. In this case this material need not necessarily have a mathematically exact composition according to the above formula, but rather, it can comprise one or more dopants and additional constituents. For the sake of simplicity, however, the above formula only includes the essential constituents of the crystal lattice (Al or As, Ga, In, P), even if these can be replaced in part by small amounts of further substances.

In this connection, “based on arsenide compound semiconductor material” means that the semiconductor layer sequence or at least one part thereof, particularly preferably at least the active zone, preferably comprises AlₙGaₗ₋ₙAs, where 0≦n≦1. In this case, this material need not necessarily have a mathematically exact composition according to the above formula, but rather, it can comprise one or more dopants and additional constituents. For the sake of simplicity, however, the above formula only includes the essential constituents of the crystal lattice (Al, Ga, As), even if these can be replaced in part by small amounts of further substances.

In the exemplary embodiment illustrated in FIG. 1, the structural units 5 are formed in a continuous or closed layer 50. The layer 50 has, for example, a continuous or closed part from which the structural units 5 project in the main emission direction 6.

However, the layer 50 in which the structural units are formed can also be a non-continuous or non-closed layer, which e.g. substantially consists of the structural units 5 spaced apart from one another, see FIG. 2. In the case where the structural units are cutouts in the layer 50, the layer 50 can correspondingly have perforations.

In the exemplary embodiment illustrated in FIG. 3, the structural units 5 are formed by cutouts in a layer 50.

In the exemplary embodiments illustrated in FIGS. 1 and 2, the regions between the structural units 5 are filled with air, for example. In the exemplary embodiment illustrated in FIG. 3, the structural units consist, for example, of cutouts filled with air. Instead of air, the regions between structural units 5 or the structural units 5 themselves can comprise, in principle, any other gaseous, liquid and/or solid substances. It is important for there to be a significant refractive index jump between the structural units 5 and the laterally adjoining regions. The refractive indices of the structural units and of the laterally adjoining regions can differ from one another for example by 1, by 2 or by more than 2.

The structural units 5 are, for example, all or at least for the most part substantially of identical size and shaped identically. However, they can also have slight differences with regard to one or more of their characteristic size parameters.

Possible characteristic size parameters are, for example, a first lateral extension, a second lateral extension measured perpendicularly to the first lateral extension, and the vertical extension. At least one of these parameters can deviate in the structural units for example by at most 10%, by at most 8% or by at most 5% from the corresponding size parameter of the other structural units.

A further possible characteristic size parameter of the structural units is the area of a projection of the structural units onto a main extension plane of the active layer 2. The area of the structural units 5 can deviate for example by 17%, by 13% or by 7% from the corresponding area of the respective other structural units. In a portion of the structural units, the size parameters can in principle also deviate to a higher degree from the corresponding size parameters of the other structural units.

In the semiconductor chips illustrated in FIGS. 1 to 3, the structural units 5 are arranged in an arbitrary statistical distribution. The distribution of the structural units meets the boundary condition that the distribution of the distances of the nearest neighbors has a standard deviation of at least +/−10% and at most +/−25% from an average value. Such a distribution is illustrated for example in FIG. 4, which shows a schematic plan view of an arrangement of structural units 5.

Such an arrangement of structural units 5 having an arbitrary statistical distribution can be produced by means of natural lithography, for example. For this purpose, by way of example, spherical beads or differently shaped bodies can be used as mask bodies for an etching process. In this case, the layer 50 in which the structural units 5 are to be formed is etched selectively at the locations which are not covered by a mask body.

By way of example, a dry etching method can be employed. By way of example, polystyrene bodies or silicon dioxide bodies can be used as mask bodies. These bodies are applied to the layer 50 for example by means of a liquid containing water, alcohol or a mixture of water and alcohol. The application is effected for example by means of the body to which the mask bodies are to be applied being dipped into the liquid. Alternatively, the liquid can be applied to the body by spin coating, for example.

In order that the boundary condition mentioned above is met, the mask bodies can, for example, initially be applied with a lower density than is finally provided. Afterward, the bodies can then be pushed together in a targeted manner, for example mechanically. An arbitrary statistical distribution is maintained in this case.

In principle, structural units in the form of cutouts can also be produced by the same method. By way of example, a negative photoresist can be applied to the layer 50 and the mask bodies can be used as an exposure mask for said photoresist. Afterward, the photoresist can be selectively removed in the regions in which the mask bodies were arranged, and a multiplicity of structural units 5 in the form of cutouts can be produced by means of etching, for example dry etching.

Further exemplary production methods can additionally or alternatively comprise the use of nano-imprint, electron beam lithography, interference lithography and/or phase mask lithography.

The exemplary embodiments of the semiconductor chip as illustrated in FIGS. 1 to 3 in each case have a reflector layer 7, which is disposed upstream of the semiconductor layers 2, 3, 4 with respect to the main emission direction 6.

The reflector layer 7 comprises an electrically insulating layer 71 and a metallically conductive layer 72. The electrically insulating layer 71 has perforations 73, such that the metallically conductive material of the layer 72 can be led through the latter. The metallically conductive material 72 serves for leading electric current into the semiconductor layers of the semiconductor chip. In principle, at least one electrically conductive layer which does not consist of or comprise a semiconductor material can be arranged between the reflector layer 7 and the semiconductor layers 2, 3, 4. By way of example, a layer comprising a transparent, electrically conductive oxide (TCO) can be arranged between the semiconductor layers 2, 3, 4 and the reflector layer 7.

In principle, the semiconductor chips can also be free of a reflector 7. A reflector 7 is advantageous, however, for the production of a directional emission characteristic of the semiconductor chip in combination with the arrangement of the structural units 5.

The main emission direction 6 and emission directions 9 at a limiting angle 91 are illustrated by means of arrows in FIG. 1. Compared with a semiconductor chip without the structural units 5, what can be achieved with a semiconductor chip as illustrated in FIGS. 1 to 3 is that a very much greater proportion of the electromagnetic radiation is emitted within an emission angle 91. By way of example, a large part of the electromagnetic radiation is emitted within an emission cone of +/−30°.

The semiconductor chip illustrated in FIG. 1 has a carrier body 8. The reflector layer 7 is arranged between the carrier body 8 and the semiconductor layers 2, 3, 4. By way of example, an electrically conductive semiconductor material can be used as the carrier body.

All the above-described exemplary embodiments of the semiconductor chip are for example free of an epitaxial substrate. It goes without saying that the semiconductor chip can also be realized with an epitaxial substrate. For the production of a directional emission characteristic, however, it is advantageous if the epitaxial substrate for producing the semiconductor chip is at least partly or completely removed.

In addition or as an alternative to the exemplary embodiments explained with reference to FIGS. 1 to 3, the structural units 5 can also extend over a plurality of layers, that is to say that the cutouts can also be made deeper than illustrated in the figures. By way of example, the layer 50 can comprise a plurality of layers of different materials. It is also possible for the cutouts for forming structural units 5 to extend partly into the semiconductor layer sequence 2, 3, 4 or completely through the latter.

FIGS. 5A, 5B to 8A, 8B schematically illustrate four different exemplary embodiments of a possible structural unit 5 in each case both in a side view and in a plan view.

In the exemplary embodiment illustrated in FIGS. 5A and 5B, the structural unit 5 is a body having a lateral cross-sectional area that is substantially constant in a vertical direction. In a plan view, the structural unit 5 has an approximately circular area (see FIG. 5B), but other area shapes such as rectangles, squares, etc. are also possible. The vertical extent 53 is identified in FIG. 5A, and a first lateral extent 51, the second lateral extent 52 and the area 54 are identified in FIG. 5B. The area 54 corresponds to the area of a projection of the structural unit 5 on a main extension plane of the active zone of the chip.

The structural unit 5 illustrated in FIGS. 6A and 6B likewise has an approximately circular shape in plan view. Expressed in general terms, the first lateral extent 51 and the second lateral extent 52 of the structural unit 5 can be approximately of identical size. In contrast to the above-described structural unit, the structural unit 5 illustrated in FIGS. 6A and 6B has a shape tapering in a vertical direction or in the main emission direction, see FIG. 6A.

The structural unit 5 illustrated in FIGS. 7A and 7B has a side which faces in the main emission direction and which contains e.g. a plurality of curvatures. The first lateral extent 51 and the second lateral extent 52 differ in size. In a plan view, the structural unit 5 has an irregular and asymmetrical shape.

FIGS. 8A and 8B illustrate an example of a structural unit 5 formed with a cutout in a layer 50. The vertical extent 52 is the depth of the cutout.

The invention is not restricted to the exemplary embodiments by the description of the invention on the basis of said exemplary embodiments. Moreover, the invention encompasses any novel feature and also any combination of features, which in particular includes any combination of features in the patent claims, even if this feature or this combination itself is not explicitly specified in the patent claims or exemplary embodiments.

1. An optoelectronic semiconductor chip comprising:
an active layer provided for emitting an electromagnetic radiation; and
a two-dimensional arrangement of structural units, which is disposed downstream of the active layer in a main emission direction of the semiconductor chip,
wherein the structural units each have a first lateral extent, a second lateral extent measured perpendicularly to the first lateral extent, and/or a vertical extent, which is greater than or equal to 0.2 times a wavelength of the emission maximum of the electromagnetic radiation and less than or equal to 5 times a wavelength of the emission maximum of the electromagnetic radiation, and
wherein the structural units are arranged in an arbitrary statistical distribution, with the boundary condition that the distribution of the distances of the nearest neighbors has a standard deviation of at least +/−10% and at most +/−25% from an average value.

2. The semiconductor chip as claimed in claim 1,
wherein the first lateral extent, the second lateral extent and the vertical extent of the structural units are each greater than 0.2 times a wavelength of the emission maximum of the electromagnetic radiation.

3. The semiconductor chip as claimed in claim 1, wherein the first lateral extent, the second lateral extent and the vertical extent of the structural units are each less than 5 times a wavelength of the emission maximum of the electromagnetic radiation.

4. The semiconductor chip as claimed in claim 1, wherein the first lateral extent, the second lateral extent and/or the vertical extent of the structural units in each case deviates by less than or at most 10% from the corresponding value of the other structural units.

5. The semiconductor chip as claimed in claim 1, wherein the area of a projection of the structural units onto a main extension plane of the active layer in each case deviates by less than or at most 20% from the corresponding area of the other structural units.

6. The semiconductor chip as claimed in claim 1, wherein the first lateral extent, the second lateral extent and/or the vertical extent is in each case of substantially identical magnitude for the majority of the structural units or for all the structural units.

7. The semiconductor chip as claimed in claim 1, wherein the majority of the structural units or all the structural units are substantially of identical size and shaped identically.

8. The semiconductor chip as claimed in claim 1, wherein the structural units are formed in a layer comprising semiconductor material.

9. The semiconductor chip as claimed in claim 8, wherein the layer terminates a semiconductor layer sequence of the semiconductor chip in the main emission direction.

10. The semiconductor chip as claimed in claim 1, wherein the active layer is part of an epitaxial semiconductor layer sequence which is provided with a reflector layer on a side lying opposite the main emission side of the semiconductor chip.

11. The semiconductor chip as claimed in claim 10, wherein the semiconductor chip is free of an epitaxial substrate.

12. The semiconductor chip as claimed in claim 10, wherein a carrier element is contained and the reflector layer is arranged between the carrier element and the semiconductor layer sequence.

13. The semiconductor chip as claimed in claim 1, wherein the area of a projection of the structural units onto a main extension plane of the active layer in each case deviates by less than or at most 15% from the corresponding area of the other structural units.

14. The semiconductor chip as claimed in claim 1, wherein the area of a projection of the structural units onto a main extension plane of the active layer in each case deviates by less than or at most 10% from the corresponding area of the other structural units.
